(19) United States
(12) Patent Application Publication
(10) Pub. No.: US 2020/0194556 A1
(43) Pub. Date: Jun. 18, 2020

(54) COMPOUND SEMICONDUCTOR DEVICE, MANUFACTURING METHOD THEREOF, AND INFRARED DETECTOR

(71) Applicant: FUJITSU LIMITED, Kawasaki-shi (JP)

(72) Inventor: Shigekazu Okumura, Setagaya (JP)

(73) Assignee: FUJITSU LIMITED, Kawasaki-shi (JP)

(21) Appl. No.: 16/691,671

(22) Filed: Nov. 22, 2019

(30) Foreign Application Priority Data
Dec. 12, 2018 (JP) 2018-232249

(51) Int. Cl. H01L 29/15; H01L 29/205; H01L 29/24; H01L 21/02

(52) U.S. Cl. CPC H01L 29/151; H01L 29/205; H01L 21/02507; H01L 21/02395; H01L 21/02428; H01L 29/24

(57) ABSTRACT

An apparatus includes a semiconductor substrate, a semiconductor layer, and a first conduction-type contact layer. The semiconductor layer that is provided above the semiconductor substrate, has a lattice constant different from a lattice constant of indium arsenide (InAs), and is formed from a semiconductor containing antimonide (Sb). The first conduction-type contact layer including a first conduction-type InAsSb layer provided over the semiconductor layer and a first conduction-type InAs layer provided over the first conduction-type InAsSb layer.

### CROSS-REFERENCE TO RELATED APPLICATION

This application is based upon and claims the benefit of priority of the prior Japanese Patent Application No. 2018-232249, filed on Dec. 12, 2018, the entire contents of which are incorporated herein by reference.

### FIELD

The embodiment discussed herein is related to a compound semiconductor device, a manufacturing method thereof, and an infrared detector.

### BACKGROUND

For example, an indium arsenide/gallium antimonide (InAs/GaSb) superlattice structure provided over a GaSb substrate has a Type-II band lineup. A compound semiconductor device including such a Type-II superlattice (T2SL) structure is applicable to an infrared detector having sensitivity in a wavelength range from mid wavelength infrared (MW) to long wavelength infrared (LW) by adjusting the film thickness and periodicity of the superlattice.

Such a T2SL infrared detector has a longer minority carrier lifetime than a quantum dot infrared photodetector (QDIP) structure and a quantum well infrared photodetector (QWIP) structure that utilize light absorption between sub-bands, and thus reduction of dark current and increase in sensitivity are expected.

Japanese Laid-open Patent Publication Nos. 2014-157994 and 2016-009716 are examples of related art.

### SUMMARY

According to an aspect of the embodiments, an apparatus comprising: a semiconductor substrate; a semiconductor layer that is provided above the semiconductor substrate, has a lattice constant different from a lattice constant of indium arsenide (InAs), and is formed from a semiconductor containing antimonide (Sb); and a first conduction-type contact layer including a first conduction-type InAsSb layer provided over the semiconductor layer and a first conduction-type InAs layer provided over the first conduction-type InAsSb layer.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a section view of a compound semiconductor device according to the present embodiment illustrating a configuration thereof;

FIGS. 2A and 2B are diagrams illustrating an AFM image of an InAsSb layer (Sb content in InAsSb is 0.35%) formed by growing InAs while adding Sb thereto;

FIGS. 3A and 3B are diagrams illustrating an AFM image of an InAs layer (Sb content is 0%) formed by growing InAs without adding Sb;

FIGS. 4A and 4B are diagrams illustrating an AFM image of InAs having a film thickness of about 5 nm grown without adding Sb;

FIGS. 5A and 5B are diagrams illustrating an AFM image of InAs having a film thickness of about 10 nm grown without adding Sb;

FIGS. 6A and 6B are diagrams illustrating an AFM image of InAs having a film thickness of about 15 nm grown without adding Sb;

FIG. 7 is a section view of a compound semiconductor device according to the present embodiment illustrating a configuration thereof;

FIG. 8 is a section view of a compound semiconductor device according to the present embodiment illustrating a configuration thereof;

FIG. 9 is a section view of a compound semiconductor device according to the present embodiment illustrating a configuration thereof;

FIG. 10 is a section view of a compound semiconductor device according to the present embodiment illustrating a configuration thereof;

FIG. 11 is a section view of a compound semiconductor device according to the present embodiment illustrating a configuration thereof;

FIG. 12 is a section view of a compound semiconductor device according to the present embodiment illustrating a configuration thereof;

FIG. 13 is a section view for explaining a configuration of a compound semiconductor device of a specific configuration example of the present embodiment and a manufacturing method thereof;

FIG. 14 is a section view for explaining a configuration of a compound semiconductor device of a specific configuration example of the present embodiment and a manufacturing method thereof;

FIG. 15 is a section view for explaining a configuration of a compound semiconductor device of a specific configuration example of the present embodiment and a manufacturing method thereof;

FIG. 16 is a section view for explaining a configuration of a compound semiconductor device of a specific configuration example of the present embodiment and a manufacturing method thereof;

FIG. 17 is a section view of an infrared detector according to the present embodiment illustrating a configuration thereof; and

FIG. 18 is a perspective view of the infrared detector according to the present embodiment illustrating the configuration thereof.

### DESCRIPTION OF EMBODIMENTS

In a compound semiconductor device constituting a T2SL infrared detector, an InAs layer may be provided as a cap layer (contact layer) over a Type-II InAs/GaSb superlattice structure. However, it has been found that, when an InAs layer is provided as a contact layer over a GaSb layer serving as an uppermost layer of the InAs/GaSb superlattice structure, pits are formed, dangling bonds are formed in the surface of the pits to form carrier traps, and therefore it is difficult to realize reduction of dark current and increase in the sensitivity.

In addition to this, for example, the same problem arises in the case of providing an InAs layer as a contact layer over a semiconductor layer such as an InAsSb layer or an aluminum antimonide (AlSb) layer. That is, the problem described above arises in the case of providing an InAs layer as a contact layer over a semiconductor layer having a lattice constant different from that of InAs and formed from a semiconductor containing Sb.

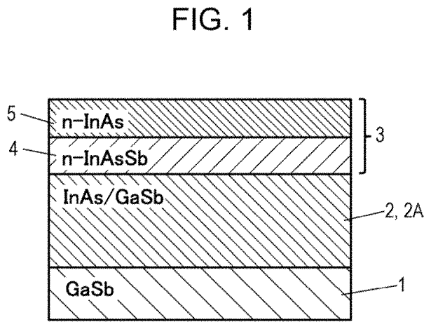

Hereinafter, a compound semiconductor device according to an embodiment, a manufacturing method thereof, and an infrared detector will be described with reference to FIGS. 1 to 18. The compound semiconductor device according to the present embodiment is, for example, a compound semiconductor device including a Type-II InAs/GaSb superlattice structure provided over a GaSb substrate, and is applied to, for example, an infrared detector having sensitivity in a wavelength range from mid wavelength infrared to long wavelength infrared by adjusting the film thickness and periodicity of the superlattice.

The superlattice structure will be also referred to as a compound semiconductor structure or a compound semiconductor lamination structure. The compound semiconductor device is constituted by a compound semiconductor lamination structure including a superlattice structure. The compound semiconductor lamination structure will be also referred to as an epitaxial structure. As illustrated in FIG. 1, in the present embodiment, the compound semiconductor device includes a GaSb substrate (semiconductor substrate) 1, an active layer 2 provided above the GaSb substrate 1 and including an InAs/GaSb superlattice structure (Type-II InAs/GaSb superlattice structure) 2A, and a contact layer 3 provided over the active layer 2.

The active layer 2 includes a GaSb layer as an uppermost layer thereof. The contact layer 3 is doped to be an n-type or a p-type (n-type herein). Therefore, the contact layer 3 will be also referred to as a first conduction-type contact layer. The contact layer 3 will be also referred to as an upper contact layer. The contact layer 3 has a bilayer structure (bilayer contact structure) including an InAsSb layer (InAs₁₋ₓSbₓ (0<x<1) layer) 4 provided over the GaSb layer constituting the uppermost layer of the active layer 2 and an InAs layer 5 provided over the InAsSb layer 4. That is, the contact layer 3 has a bilayer InAsSb/InAs contact structure.

As described above, while the InAsSb layer 4 in which generation of pits is suppressed is used for the contact layer 3, the InAsSb layer 4 is coated by the InAs layer 5 to suppress oxidation of the surface thereof. The InAsSb layer 4 and the InAs layer 5 constituting the contact layer 3 are each doped to be an n-type or a p-type (n-type herein). Therefore, the InAsSb layer 4 will be also referred to as a first conduction-type InAsSb layer. In addition, the InAs layer 5 will be also referred to as a first conduction-type InAs layer.

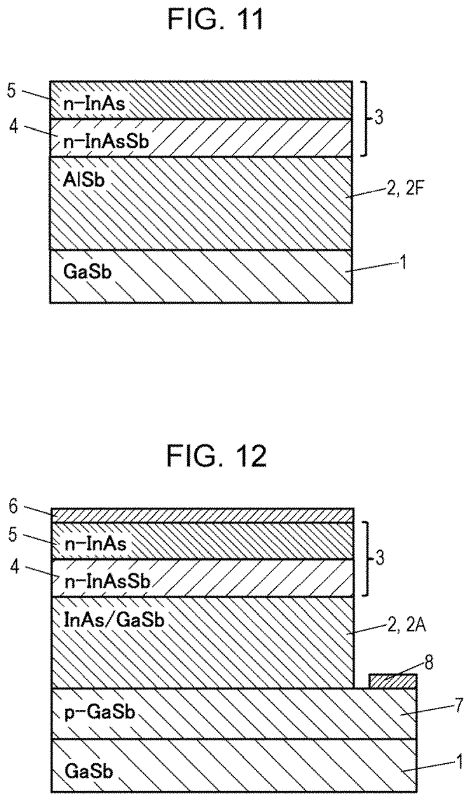

The contact layer 3 preferably has a thickness of about 20 nanometers (nm) or more. The contact layer 3 more preferably has a thickness of about 30 nm or more. The purpose of this is to secure performance of the contact layer 3. For example, since a metal electrode 6 is to be formed over the contact layer 3 (for example, see FIG. 12), the thickness is set to this value so as to suppress diffusion of metal elements constituting the metal electrode 6 into the active layer 2 through the contact layer 3.

The InAs layer 5 preferably has a thickness of about 10 nm or less. This is based on results of study that will be described later, and the InAs layer 5 may be formed without generation of pits in this range. The InAsSb layer 4 preferably has a thickness of about 10 nm or more. This is because while the thickness of the InAs layer 5 is preferably smaller to suppress generation of pits, a certain thickness is preferably secured for the contact layer as a whole.

The InAsSb layer 4 is preferably an InAs₁₋ₓSbₓ layer (0.0035≤x≤0.0065). In this description, x=0.0035 indicates an Sb content of 0.35%, and as will be described later in results of study, this is based on the fact that pits are not formed when Sb is contained by about this amount. In addition, x=0.0065 indicates an Sb content of 0.65%, and this value is set because the band offset between InAs and Sb becomes large to affect electrical conduction when the Sb content is too high. Since only a small amount of Sb is added in this case, the electrical conduction is not affected, and the performance of the contact layer is not degraded.

As described above, in the case of providing the InAs layer 5 as the contact layer 3 over the GaSb layer constituting the uppermost layer of the active layer 2 including the Type-II InAs/GaSb superlattice structure 2A, the InAsSb layer 4 is interposed between the GaSb layer and the InAs layer 5, and thus the bilayer InAsSb/InAs contact structure is formed. As a result of this, by securing a thickness preferable for the contact layer 3 by the InAsSb layer 4 in which generation of pits is suppressed, oxidation of the surface of Sb which is easily oxidized is suppressed while suppressing generation of pits (defects) in the InAs layer 5 by reducing the thickness of the InAs layer 5 provided on the surface side. The contact resistance may be also reduced by reducing a Schottky barrier.

In this manner, generation of pits in the contact layer 3 may be suppressed, carrier traps may be suppressed, and reduction of dark current and increase in the sensitivity (increase in the sensitivity of the infrared detector) may be realized. Particularly, in the case where the active layer 2 includes a superlattice structure, growing is performed at a low temperature. Generation of pits in the contact layer 3 is likely to occur in the case of performing growing at a low temperature. Therefore, in the case where the active layer 2 includes a superlattice structure, by employing the contact layer 3 having the configuration described above, generation of pits may be suppressed, carrier traps may be suppressed, and reduction of dark current and increase in the sensitivity may be realized.

The reason why the above-discussed configuration is employed will be described below. In a compound semiconductor device constituting a T2SL infrared detector, an InAs layer may be provided as a cap layer (contact layer) over a Type-II InAs/GaSb superlattice structure. The purpose for this is to reduce the contact resistance by reducing the Schottky barrier and suppress oxidation of the surface caused by Sb which is easily oxidized.

However, it has been found that, when an InAs layer is provided as a contact layer over a GaSb layer serving as an uppermost layer of the InAs/GaSb superlattice structure, pits are formed, dangling bonds are formed in the surface of the pits to form carrier traps, and therefore it is difficult to realize reduction of dark current and increase in the sensitivity. Therefore, the following study was carried out.

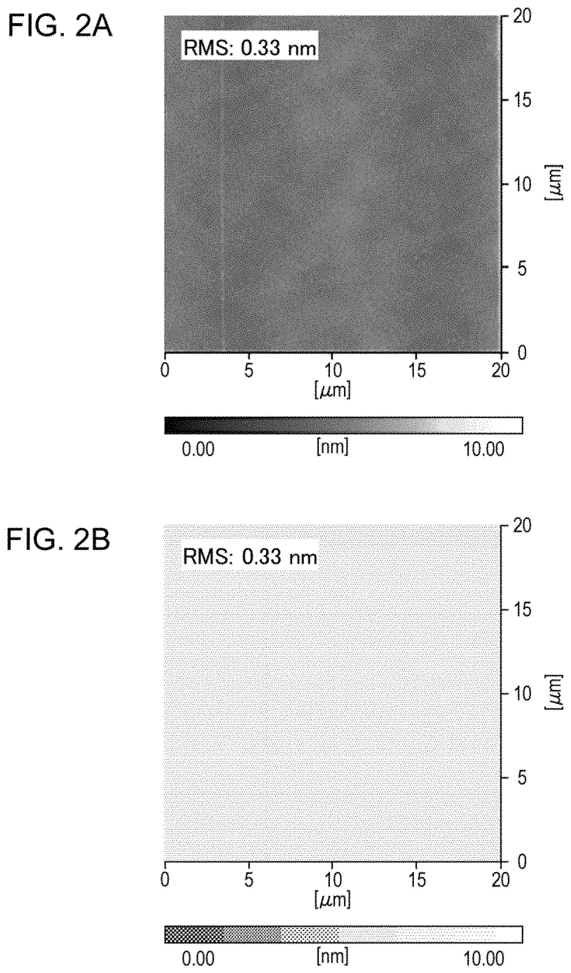

First, growing InAs by molecular beam epitaxy (MBE) growth over GaSb was attempted while adding Sb thereto. FIG. 2A illustrates an atomic force microscope (AFM) image (about 20 μm×about 20 μm) of an InAsSb layer (Sb content in InAsSb: 0.35%, composition: InAs_{0.9965}Sb_{0.0035}, thickness: about 100 nm) formed by growing InAs while adding Sb thereto. FIG. 2B is a schematic diagram of FIG. 2A.

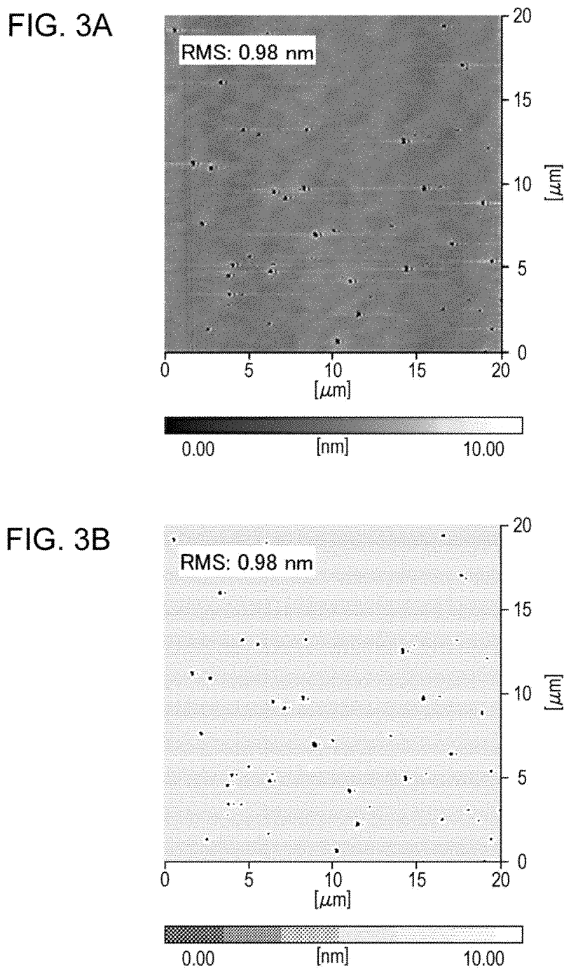

FIG. 3A illustrates an AFM image (about 20 μm×about 20 μm) of an InAs layer (Sb content: 0%, thickness: about 100 nm) formed by growing InAs without adding Sb. FIG. 3B is a schematic diagram of FIG. 3A. While pits (see black dots of FIGS. 3A and 3B) are formed in the InAs layer (Sb content: 0%) as illustrated in FIGS. 3A and 3B, pits are not formed in the InAsSb layer (Sb content: 0.35%) as illustrated in FIGS. 2A and 2B.

As described above, the pits in the surface are suppressed by adding Sb. This is considered to be because Sb atoms function as surfactants in the surface while growing InAs, and suppress progress of three-dimensional growth of InAs. Next, the film thickness dependency of growth of InAs over GaSb was investigated in the case of growing InAs without adding Sb.

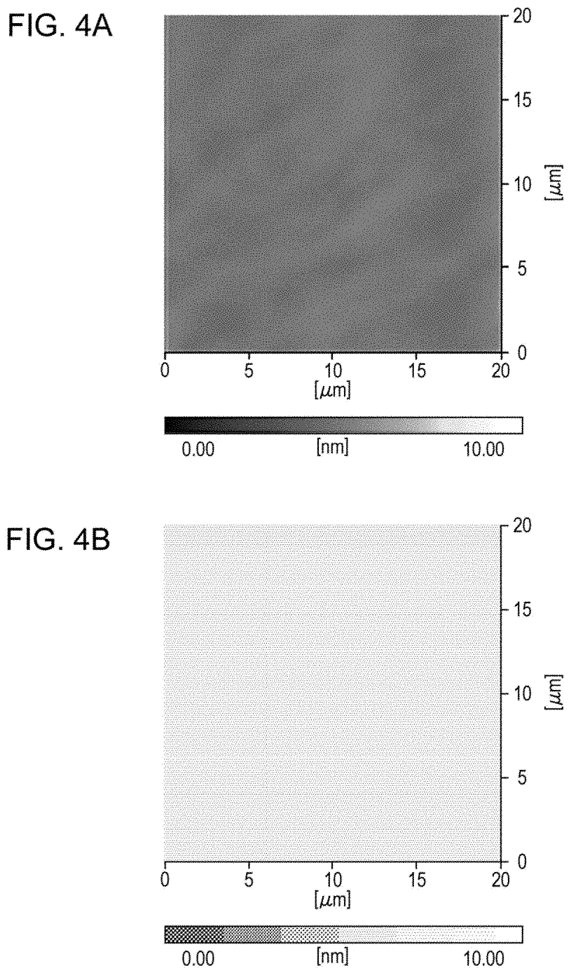

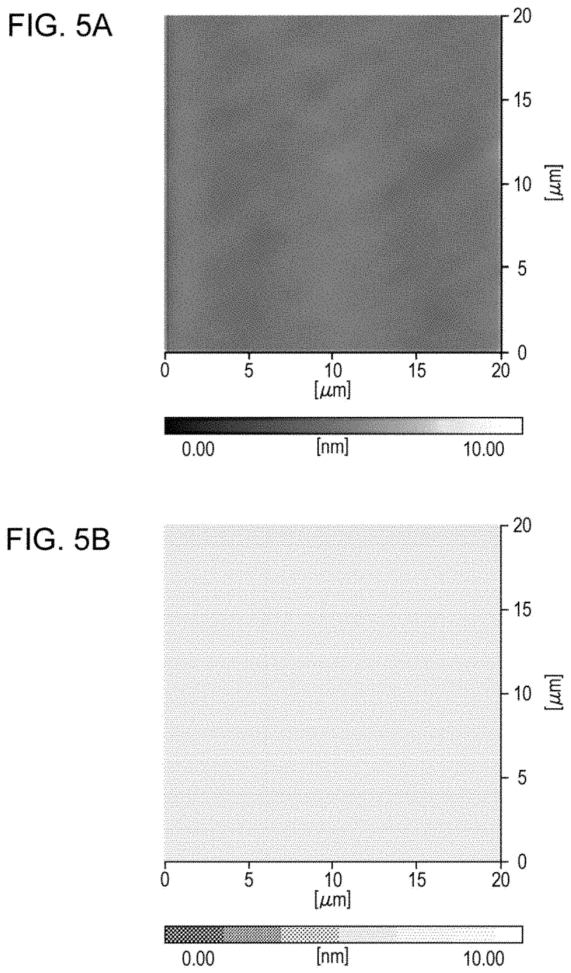

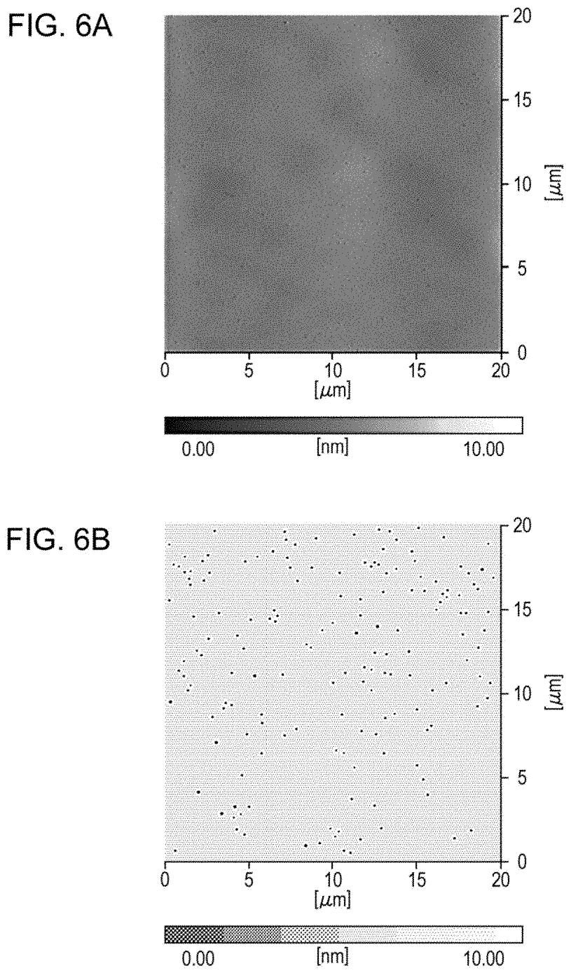

FIGS. 4A to 6B illustrate AFM images (about 20 μm×about 20 μm) of InAs in the cases where the film thickness thereof was about 5 nm, where the film thickness thereof was about 10 nm, and where the film thickness thereof was about 15 nm, respectively. FIG. 4B is a schematic diagram of FIG. 4A. As illustrated in FIGS. 4A and 5A, whereas InAs grew without generation of pits in the cases where the film thickness thereof was about 5 nm and where the film thickness thereof was about 10 nm, pits were generated in the case where the film thickness of InAs was about 15 nm as illustrated in FIG. 6A. FIG. 5B is a schematic diagram of FIG. 5A, and FIG. 6B is a schematic diagram of FIG. 6A.

As described above, it has been found that growth of InAs without generation of pits may be possible when the film thickness thereof is equal to or smaller than about 10 nm. As a result of this study, it has been found that the contact layer 3 in which generation of pits is suppressed (preferably prevented) may be realized by forming the contact layer 3 to have a bilayer structure including the InAsSb layer 4 as a lower layer and the InAs layer 5 as an upper layer (preferably the InAs layer 5 having a thickness of about 10 nm or less).

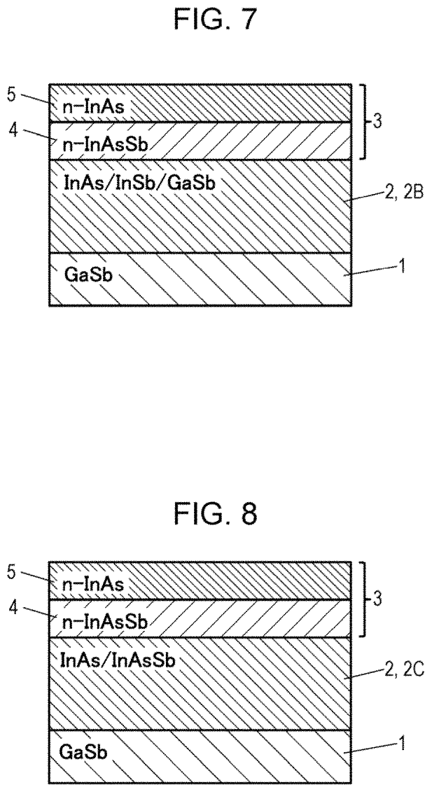

Therefore, the configuration described above is employed, and thus generation of pits in the contact layer 3 may be suppressed, carrier traps may be suppressed, and reduction of dark current and increase in the sensitivity may be realized. Although the active layer 2 is formed to include the InAs/GaSb superlattice structure 2A in which an InAs layer and a GaSb layer are laminated in this example, the configuration is not limited to this, and for example, an InSb layer may be provided between the InAs layer and the GaSb layer for compensation for distortion. That is, the active layer 2 may be formed to have an InAs/InSb/GaSb superlattice structure (Type-II InAs/InSb/GaSb superlattice structure) 2B instead of the InAs/GaSb superlattice structure 2A as illustrated in FIG. 7.

Further, although the active layer 2 is formed to include the undoped InAs/GaSb superlattice structure 2A in this example, the configuration is not limited to this, and for example, the active layer 2 may be formed to have a pin structure in which an InAs/GaSb superlattice structure doped to be a p-type, an undoped InAs/GaSb superlattice structure, and an InAs/GaSb superlattice structure doped to be an n-type are laminated.

Although there is a case where the active layer 2 includes a doped semiconductor layer as described above, since the contact layer 3 is doped to a higher concentration, the doping concentration of the contact layer 3 is higher than the doping concentration of the semiconductor layer constituting the active layer 2. Although a configuration for solving a problem that arises in the case where the InAs layer 5 is provided as the contact layer 3 over the GaSb layer constituting the uppermost layer of the active layer 2 including the InAs/GaSb superlattice structure 2A has been described in this example, the configuration is not limited to this.

The same problem also arises in the case where, for example, the InAs layer 5 is provided as the contact layer 3 over a semiconductor layer such as an InAsSb layer or an AlSb layer, that is, where the InAs layer 5 is provided as the contact layer 3 over a semiconductor layer having a lattice constant different from that of InAs and formed from a semiconductor containing Sb, and the contact layer 3 having the bilayer InAs/InAsSb contact structure described above may be also employed as a configuration for solving this problem.

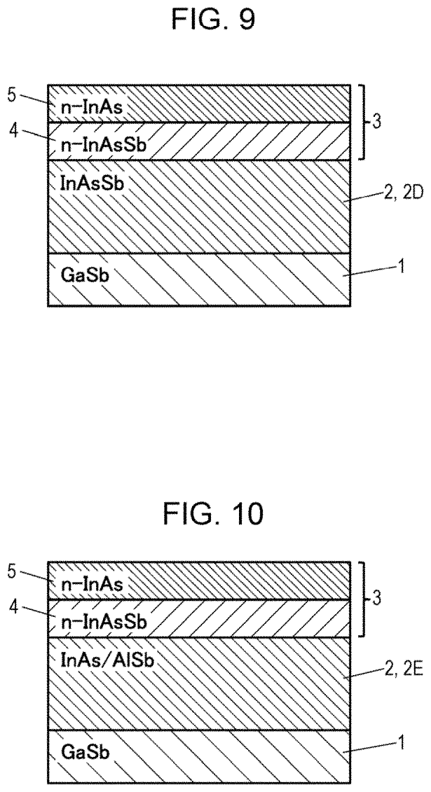

That is, a case where the layer under the contact layer 3 is a GaSb layer is described as an example herein. However, the configuration is not limited to this, and the layer under the contact layer 3 may be, for example, an InAsSb layer or an AlSb layer. Examples of the case where the layer under the contact layer 3 is an InAsSb layer include a case where the active layer 2 includes an InAs/InAsSb superlattice structure (Type-II InAs/InAsSb superlattice structure) 2C and the InAsSb layer is included as the uppermost layer thereof as illustrated in FIG. 8, and a case where the active layer 2 is formed as an InAsSb bulk layer 2D as illustrated in FIG. 9.

That is, the active layer 2 may include the InAs/InAsSb superlattice structure (Type-II InAs/InAsSb superlattice structure) 2C in which an InAsSb layer and an InAs layer are laminated, or may be the InAsSb bulk layer 2D. The InAs/InAsSb superlattice structure 2C may be undoped or be a pin structure. Examples of the case where the layer under the contact layer 3 is an AlSb layer include a case where the active layer 2 includes an InAs/AlSb superlattice structure (Type-II InAs/AlSb superlattice structure) 2E and the AlSb layer is included as the uppermost layer thereof as illustrated in FIG. 10, and a case where the active layer 2 is formed as an AlSb bulk layer 2F as illustrated in FIG. 11.

That is, the active layer 2 may have the InAs/AlSb superlattice structure (Type-II InAs/AlSb superlattice structure) 2E in which an AlSb layer and an InAs layer are laminated, or may be the AlSb bulk layer 2F. The InAs/AlSb superlattice structure 2E may be undoped or be a pin structure. The active layer 2 may be constituted by a combination of these superlattice structures 2A, 2B, 2C, 2E, and the bulk layers 2D and 2F.

For example, a part of the active layer 2 including the InAs/GaSb superlattice structure 2A described above may be replaced by the InAs/AlSb superlattice structure 2E. That is, the active layer 2 may be formed to include the InAs/GaSb superlattice structure 2A and the InAs/AlSb superlattice structure 2E. Further, for example, the AlSb bulk layer 2F may be provided between two parts of the InAs/GaSb superlattice structure 2A constituting the active layer 2 including the InAs/GaSb superlattice structure 2A, or the AlSb bulk layer 2F may be provided over the InAs/GaSb superlattice structure 2A. That is, the active layer 2 may be formed to include the InAs/GaSb superlattice structure 2A and the AlSb bulk layer 2F.

Although the active layer 2 is formed to include the superlattice structure (superlattice layer) 2A, 2B, 2C, or 2E or formed as the bulk layer 2D or 2F in this example, the configuration is not limited to this, and for example, the active layer 2 may be formed to have a quantum well structure (Type-II quantum well structure) or a quantum dot structure (Type-II quantum dot structure). In the case of forming the active layer 2 in this manner, the active layer 2 has a structure containing at least one of Al, In, Ga, As, and Sb.

As described above, the layer under the contact layer 3 may be a semiconductor layer (at least one of 2 and 2A to 2F) having a lattice constant different from that of InAs and formed from a semiconductor containing Sb. This is because it is considered that the cause of the problem that arises in the case of providing the InAs layer 5 as the contact layer 3 lies in the difference in the lattice constant between InAs and the semiconductor (semiconductor material) used as the underlayer.

In this case, the compound semiconductor device includes the semiconductor substrate 1, a semiconductor layer (at least one of 2 and 2A to 2F) that is provided above the semiconductor substrate 1, has a lattice constant different from a lattice constant of InAs, and is formed from a semiconductor containing Sb, and the first conduction-type contact layer 3 including the first conduction-type InAsSb layer 4 provided over the semiconductor layer and the first conduction-type InAs layer 5 provided over the first conduction-type InAsSb layer 4.

The semiconductor layer may be a GaSb layer, an InAsSb layer, or an AlSb layer. In the case described above, the semiconductor layer described above constitutes the active layer 2. The active layer 2 includes the superlattice structure 2A including an InAs layer and a GaSb layer, the superlattice structure 2C including an InAs layer and an InAsSb layer, the superlattice structure 2E including an InAs layer and an AlSb layer, the InAsSb bulk layer 2D, or the AlSb bulk layer 2F. The semiconductor layer does not have to be a semiconductor layer constituting an active layer, and, for example, may be a semiconductor layer interposed between the contact layer 3 and the active layer 2.

In the present embodiment, the compound semiconductor device includes a first metal electrode 6 provided over the contact layer (upper contact layer) 3 as illustrated in FIG. 12. In this example, the first metal electrode 6 is provided over the InAs layer 5 constituting the contact layer 3. Further, in the present embodiment, the compound semiconductor device includes a contact layer (lower contact layer) 7 provided between the GaSb substrate 1 and the active layer 2.

The lower contact layer 7 is doped to be an n-type or a p-type (p-type herein). Therefore, the lower contact layer 7 will be also referred to as a second conduction-type contact layer. The lower contact layer 7 is a GaSb layer formed from GaSb and doped to be an n-type or a p-type (p-type herein). Therefore, GaSb will be also referred to as a second conduction-type GaSb. Further, the GaSb layer 7 will be also referred to as a second conduction-type GaSb layer.

In the present embodiment, a second metal electrode 8 is provided over the lower contact layer 7. A method of manufacturing the compound semiconductor device having a configuration described above may include a step of forming, above the semiconductor substrate 1, a semiconductor layer (at least one of 2 and 2A to 2F) that has a lattice constant different from a lattice constant of InAs and is formed from a semiconductor containing Sb, and a step of forming the first conduction-type contact layer 3 including the first conduction-type InAsSb layer 4 and the first conduction-type InAs layer 5 by forming the first conduction-type InAsSb layer 4 over the semiconductor layer and forming the first conduction-type InAs layer 5 over the first conduction-type InAsSb layer 4 (for example, see FIGS. 1 and 7 to 12).

In this case, the semiconductor layer is a GaSb layer, an InAsSb layer, or an AlSb layer. The first conduction-type contact layer 3 has a thickness of 20 nm or more. The first conduction-type InAs layer 5 has a thickness of 10 nm or less. The first conduction-type InAsSb layer 4 has a thickness of 10 nm or more. The first conduction-type InAsSb layer 4 is preferably a first conduction-type InAs₁₋ₓSbₓ layer (0.0035≤x≤0.0065). A step of forming the first metal electrode 6 over the first conduction-type InAs layer 5 is also included.

The semiconductor layer constitutes the active layer 2. In this case, the step of forming the semiconductor layer described above is included in the step of forming the active layer 2. In the step of forming the active layer 2, for example, the active layer 2 including the superlattice structure 2A including an InAs layer and a GaSb layer, the superlattice structure 2C including an InAs layer and an InAsSb layer, the superlattice structure 2E including an InAs layer and an AlSb layer, the InAsSb bulk layer 2D, or the AlSb bulk layer 2F may be formed (for example, see FIGS. 1 and 7 to 11). The semiconductor substrate 1 may be a GaSb substrate.

A step of forming a second conduction-type contact layer 7 formed from a second conduction-type GaSb between the semiconductor substrate 1 and the active layer 2 may be included (for example, see FIG. 12). A step of forming the second metal electrode 8 over the second conduction-type contact layer 7 may be included (for example, see FIG. 12). More specific description will be given by describing a specific configuration example.

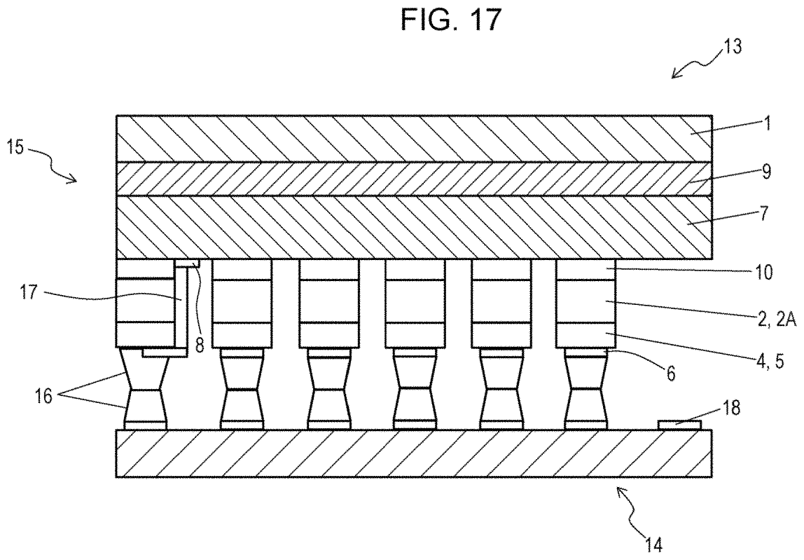

In the present specific configuration example, the compound semiconductor device includes a compound semiconductor lamination structure in which a GaSb layer (buffer layer) 9, the p-type GaSb layer (lower contact layer) 7, a p-type InAs_{0.91}Sb_{0.09} layer (etching stopper layer) 10, the active layer 2 including the InAs/GaSb superlattice structure (Type-II InAs/GaSb superlattice structure) 2A, and the upper contact layer 3 including the n-type InAs_{0.9965}Sb_{0.0035} layer 4 and the n-type InAs layer 5 are laminated over the n-type GaSb substrate 1, as illustrated in FIGS. 13 and 16.

In this example, the p-type InAsSb layer 10 provided as an etching stopper layer has a composition that lattice-matches GaSb. Using an InAs layer as the etching stopper layer is not preferable because in this case, an InAs bulk layer is grown over GaSb and pits are generated, and therefore an InAsSb layer is used herein. Further, as illustrated in FIG. 16, the surface is covered by a SiN passivation film (insulating film) 11, the first metal electrode 6 is provided over the n-type InAs layer 5 constituting the upper contact layer 3, and the second metal electrode 8 is provided over the p-type GaSb layer serving as the lower contact layer 7.

The infrared detector including this compound semiconductor device will be also referred to as an n-type InAs/InAsSb contact layer-applied T2SL infrared detector. Next, a method of manufacturing the compound semiconductor device of this specific configuration example will be described with reference to FIGS. 13 to 16. First, as illustrated in FIG. 13, the n-type GaSb substrate 1 inclined by about 0.35° (slight inclination) with respect to the (001) surface is introduced into a solid source molecular beam epitaxy (MBE) apparatus, and the substrate temperature is raised by heating the substrate by a heater.

A standard cell is used for each of material sources In, Ga, As, and Sb, and a valved cracker cell is used for As and Sb, which are group V elements. In this case, Sb is radiated onto the GaSb substrate 1 when the substrate temperature has reached a temperature of about 400° Celsius (C). For example, the beam flux of Sb is set to about 5.0×10⁻⁷ Torr (about 6.7×10⁻⁵ pascal (Pa)).

When the substrate temperature is raised further, an oxide film of the surface of GaSb is dissociated when the substrate temperature has reached a temperature of about 550° C. Then, the substrate temperature is raised to a temperature of about 570° C. while the Sb beam is radiated, the substrate temperature is maintained for about 10 minutes, and the surface oxide film is completely detached. Next, the substrate temperature is set to about 520° C. while the Sb beam is radiated, and the GaSb layer (buffer layer) 9 is formed by radiating Ga.

For example, the beam flux of Ga is set to about 5.0×10⁻⁸ Torr (about 6.7×10⁻⁶ Pa). The V/III ratio is about 10. In this condition, the GaSb growing speed is, for example, about 0.30 micrometers/hour (μm/h). Then, when the GaSb layer 9 is formed to a thickness of about 100 nm, Be is additionally radiated. Next, radiation of Ga and beryllium (Be) is continued, and thus the p-type GaSb layer (lower contact layer; second conduction-type contact layer) 7 is formed. For example, the Be cell temperature is adjusted such that the carrier concentration is about 5.0×10¹⁸ cm⁻³.

Subsequently, when the p-type GaSb layer 7 is formed to a thickness of about 500 nm, the radiation of Be and Ga is stopped, the growing temperature is reduced to about 480° C. in an Sb atmosphere, supply of Sb is stopped when once the temperature becomes stable, and thus growing is stopped for about 3 seconds. Next, Be, In, As, and Sb are radiated to form the p-type InAs_{0.91}Sb_{0.09} layer (etching stopper layer) 10.

For example, the beam flux of In is set to about 5.0×10⁻⁸ Torr (about 6.7×10⁻⁶ Pa). For example, the beam flux of As is set to about 4.0×10⁻⁷ Torr (about 5.3×10⁻⁵ Pa). For example, the beam flux of Sb is set to about 1.0×10⁻⁷ Torr (about 1.3×10⁻⁵ Pa). The V/III ratio is about 10. In this case, the growing speed of InAsSb is, for example, about 0.30 μm/h. Further, the Be cell temperature is adjusted such that the carrier concentration is about 5.0×10¹⁸ cm⁻³.

Then, radiation of Be, In, As, and Sb is stopped when the p-type InAs_{0.91}Sb_{0.09} 10 is formed to a thickness of about 100 nm, and the temperature is reduced to about 400° C. Next, the InAs/GaSb superlattice structure (Type-II InAs/GaSb superlattice structure) 2A is grown to form the active layer 2. First, In and As are radiated.

For example, the beam flux of In is set to about 5.0×10⁻⁸ Torr (about 6.7×10⁻⁶ Pa). For example, the beam flux of As is set to about 4.0×10⁻⁷ Torr (about 5.3×10⁻⁵ Pa). The V/III ratio is about 8. In this case, the growing speed of InAs is, for example, about 0.30 μm/h. Then, supply of In and As is stopped when InAs is formed to a thickness of about 2 nm.

Subsequently, growing is stopped for about 3 seconds in vacuum. Next, Ga and Sb are radiated. For example, the beam flux of Ga is set to about 5.0×10⁻⁸ Torr (about 6.7×10⁻⁶ Pa). For example, the beam flux of Sb is set to about 5.0×10⁻⁷ Torr (about 6.7×10⁻⁵ Pa). The V/III ratio is about 10. In this case, the growing speed of GaSb is, for example, about 0.30 μm/h.

Then, supply of Ga and Sb is stopped when GaSb is formed to a thickness of about 2 nm. Subsequently, growing is stopped for about 3 seconds in vacuum. This procedure of forming InAs and GaSb is referred to as one cycle (one period), and is repeated for, for example, 200 cycles (200 periods), and thus the active layer 2 including the Type-II InAs/GaSb superlattice (T2SL) structure (superlattice layer) 2A having a total thickness of about 800 nm is formed.

Next, the contact layer (upper contact layer; first conduction-type contact layer) 3 having a bilayer structure is formed. First, In, As, Sb, and Si are radiated, and thus the n-type InAs_{0.9965}Sb_{0.0035} layer (first conduction-type InAsSb layer) 4 is formed. For example, the beam flux of In is set to about 5.0×10⁻⁸ Torr (about 6.7×10⁻⁶ Pa). For example, the beam flux of As is set to about 5.0×10⁻⁷ Torr (about 6.7×10⁻⁵ Pa). For example, the beam flux of Sb is set to about 5.0×10⁻⁹ Torr (about 6.7×10⁻⁷ Pa). The V/III ratio is about 10. In this case, the growing speed of InAsSb is, for example, about 0.30 μm/h. Further, the Si cell temperature is adjusted such that the carrier concentration is about 5.0×10¹⁸ cm⁻³.

Then, supply of Sb is stopped when the n-type InAs_{0.9965}Sb_{0.0035} layer 4 is formed to a thickness of about 50 nm. Subsequently, In, As, and Si are radiated, and thus the n-type InAs layer (first conduction-type InAs layer) 5 is formed. For example, the beam flux of In is set to about 5.0×10⁻⁸ Torr (about 6.7×10⁻⁶ Pa). For example, the beam flux of As is set to about 5.0×10⁻⁷ Torr (about 6.7×10⁻⁵ Pa). The V/III ratio is about 10. In this case, the growing speed of InAs is, for example, 0.30 μm/h. For example, the Si cell temperature is adjusted such that the carrier concentration is about 5.0×10¹⁸ centimeter (cm)⁻³.

Then, supply of In and Si is stopped when the n-type InAs layer 5 is formed to a thickness of about 5 nm. Then, the temperature is reduced while an As beam is radiated, and the radiation of the As beam is stopped when the substrate temperature has reached a temperature of about 300° C. In this manner, the upper contact layer 3 having a bilayer structure including the n-type InAs_{0.9965}Sb_{0.0035} layer 4 and the n-type InAs layer 5 is formed.

After forming the compound semiconductor lamination structure in this manner, the GaSb substrate on which respective semiconductor layers have been epitaxially grown as described above (see FIG. 13) is taken out from the MBE apparatus. Then, for example, a resist pattern covering a region of about 50 μm×about 50 μm and not covering a peripheral region thereof is formed on the GaSb substrate on which the respective semiconductor layers have been epitaxially grown (see FIG. 13). In this case, the number of pixels is set to, for example, 256×256. Further, the total area is about 15.36 millimeters (mm)×about 15.36 mm.

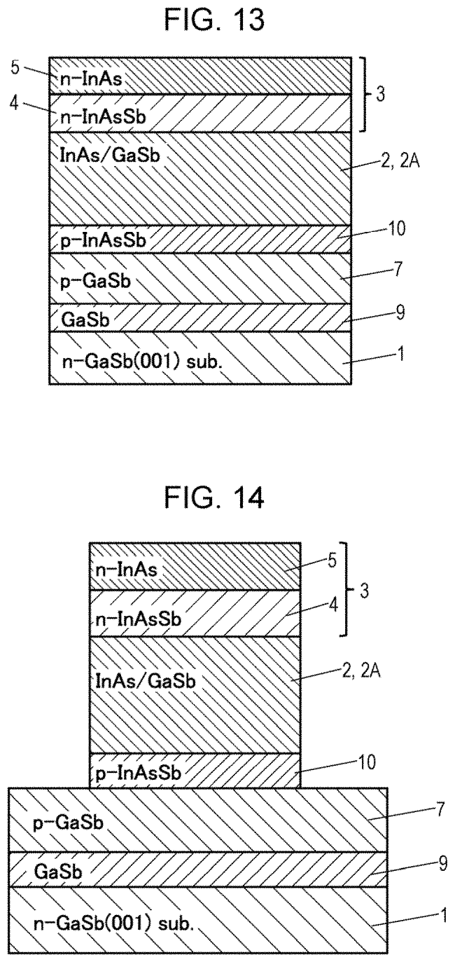

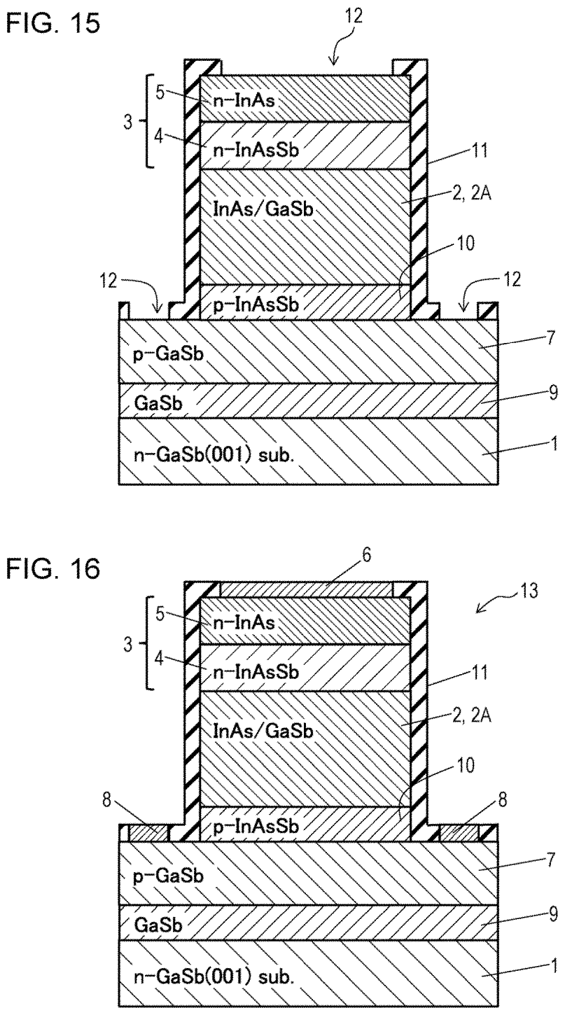

Next, the substrate is introduced into a dry etching apparatus and is etched by using, for example, a carbon tetrafluoride (CF4)-based gas, and thus a mesa structure is formed as illustrated in FIG. 14. Next, the substrate is introduced into a plasma chemical vapor deposition (CVD) apparatus, and the silicon nitride (SiN) passivation film (insulating film) 11 is formed to a thickness of, for example, about 100 nm, by using, for example, a silicon hydride (SiH₄)-based gas and an ammonia (NH₃)-based gas, as illustrated in FIG. 15.

Then, an electrode opening area is patterned by using a resist, the substrate is introduced into the dry etching apparatus again, the SiN passivation film 11 is etched by using, for example, a CF₄-based gas, and thus electrode opening areas 12 are formed. Next, the electrode opening areas 12 are patterned by using a resist again, and the first metal electrode 6 and the second metal electrodes 8 titanium/platinum/gold (Ti/Pt/Au electrodes herein) are formed by a sputtering method and a lift-off method as illustrated in FIG. 16.

In this manner, a compound semiconductor device 13 of the present specific configuration example may be manufactured. Although a case where the present embodiment is applied to a compound semiconductor lamination structure including the GaSb substrate 1 as a semiconductor substrate has been described as an example, the configuration is not limited to this, and, for example, a GaAs substrate may be used as the semiconductor substrate. In this case, the compound semiconductor lamination structure described above may be provided over the GaAs substrate with, for example, a GaInSb inclined composition layer (lattice constant difference reducing layer) therebetween.

Although a case where the n-type GaSb substrate (n-type semiconductor substrate) 1 is used has been described as an example in the present embodiment, the configuration is not limited to this, and for example, a p-type GaSb substrate (p-type semiconductor substrate) may be used. In this case, for example, the GaSb layer 9 (for example, see FIG. 16) does not have to be provided. Although a case where the p-type InAsSb layer 10 is provided as an etching stopper layer has been described as an example in the present embodiment, the configuration is not limited to this, and a configuration not including an etching stopper layer may be employed.

Although the conduction type of the substrate side (lower side) is the p-type, the conduction type of the surface side (upper side) is the n-type, for example, the lower contact layer 7 is a p-type contact layer (second conduction-type contact layer), and the upper contact layer 3 is an n-type contact layer (first conduction-type contact layer) in the present embodiment, the configuration is not limited to this, and the conduction types of the upper side and the lower side may be inverted. That is, a configuration in which the conduction type of the substrate side (lower side) is the n-type, the conduction type of the surface side (upper side) is the p-type, for example, the lower contact layer 7 is an n-type contact layer (second conduction-type contact layer), and the upper contact layer 3 is a p-type contact layer (first conduction-type contact layer) may be employed.

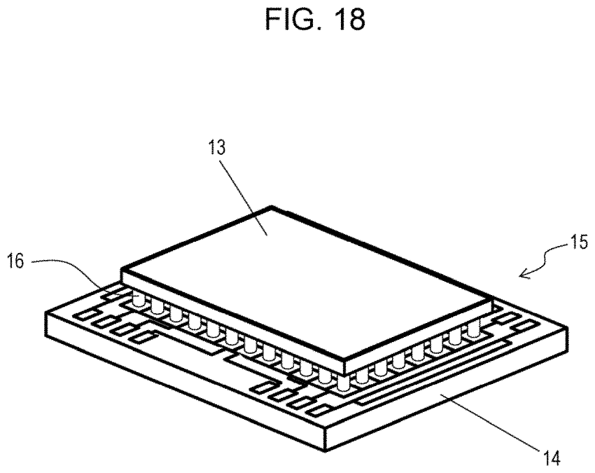

Incidentally, as illustrated in, for example, FIGS. 17 and 18, an infrared detector 15 may be constituted by coupling a readout circuit (signal readout circuit) included in a readout circuit chip 14 to the compound semiconductor device 13 having the configuration described above. In this case, the infrared detector 15 includes the compound semiconductor device 13 having the configuration described above and a readout circuit coupled to the compound semiconductor device 13.

For example, as illustrated in FIGS. 17 and 18, the infrared detector 15 may be constituted by coupling the readout circuit chip 14 including a readout circuit to the compound semiconductor device 13 having the configuration described above by flip chip bonding via bump electrodes 16. In FIG. 17, a reference sign 17 denotes an extraction electrode, and a reference sign 18 denotes an electrode. The infrared detector 15 having such a configuration detects infrared light incident from the back surface side of the GaSb substrate 1 included in the compound semiconductor device 13. The infrared detector 15 will be also referred to as a GaSb-based infrared detector.

Therefore, the compound semiconductor device according to the present embodiment and a manufacturing method thereof, and the infrared detector may suppress generation of pits in the contact layer 3, may suppress carrier traps, and may realize reduction of dark current and increase in the sensitivity. For example, by using the InAsSb/InAs bilayer contact layer 3 of the embodiment described above, generation of pits in the contact layer 3 of the T2SL infrared detector 15 may be suppressed, carrier traps may be suppressed, and increase in the sensitivity of an individual element may be realized. Further, by applying the T2SL infrared detector 15 of the present embodiment to a focal plane array (FPA) the number of defective pixels may be reduced, and the yield may be improved.

Note that the disclosure is not limited to the configurations described in the above-described embodiment and modifications, but various modifications may be made without departing from the scope of the disclosure.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. An apparatus comprising:
a semiconductor substrate;
a semiconductor layer that is provided above the semiconductor substrate, has a lattice constant different from a lattice constant of indium arsenide (InAs), and is formed from a semiconductor containing antimonide (Sb); and
a first conduction-type contact layer including a first conduction-type InAsSb layer provided over the semiconductor layer and a first conduction-type InAs layer provided over the first conduction-type InAsSb layer.

2. The apparatus according to claim 1, wherein the semiconductor layer is a gallium antimonide (GaSb) layer, an InAsSb layer, or an aluminum antimonide (AlSb) layer.

3. The apparatus according to claim 1, wherein the first conduction-type contact layer has a thickness of 20 nanometers (nm) or more.

4. The apparatus according to claim 1, wherein the first conduction-type InAs layer has a thickness of 10 nm or less.

5. The apparatus according to claim 1, wherein the first conduction-type InAsSb layer has a thickness of 10 nm or more.

6. The apparatus according to claim 1, wherein the first conduction-type InAsSb layer is a first conduction-type InAs₁₋ₓSbₓ layer (0.0035≤x≤0.0065).

7. The apparatus according to claim 1, further comprising a first metal electrode provided over the first conduction-type InAs layer.

8. The apparatus according to claim 1, wherein the semiconductor layer constitutes an active layer.

9. The apparatus according to claim 8, wherein the semiconductor substrate is a GaSb substrate or a GaAs substrate, and
the active layer includes a superlattice structure including an InAs layer and a GaSb layer, a superlattice structure including an InAs layer and an InAsSb layer, a superlattice structure including an InAs layer and an AlSb layer, an InAsSb bulk layer, or an AlSb bulk layer.

10. The apparatus according to claim 9, further comprising a second conduction-type contact layer provided between the semiconductor substrate and the active layer and formed from second conduction-type GaSb.

11. The apparatus according to claim 10, further comprising a second metal electrode provided over the second conduction-type contact layer.

12. The apparatus according to claim 1, further comprising a signal readout circuit coupled to a compound semiconductor device including the semiconductor substrate, the semiconductor layer, and the first conduction-type contact layer.

13. A method of manufacturing a compound semiconductor device, comprising:
forming a semiconductor layer, above a substrate, including antimonide (Sb) and having a lattice constant different from indium arsenide (InAs); and
forming a first conduction-type contact layer including the first conduction-type InAsSb layer and a first conduction-type InAs layer by forming a first conduction-type InAsSb layer on the semiconductor layer and the first conduction-type InAsSb layer above the first conduction-type InAs layer.

14. The method according to claim 13, wherein the semiconductor layer is a gallium antimonide (GaSb) layer, an InAsSb layer, or an aluminum antimonide (AlSb) layer.

15. The method according to claim 13, wherein the first conduction-type contact layer has a thickness of 20 nanometers (nm) or more.

16. The method according to claim 13, wherein the first conduction-type InAsSb layer has a thickness of 10 nm or more.

17. The method according to claim 13, wherein the first conduction-type InAs layer has a thickness of 10 nm or more.

18. The method according to claim 13, wherein the first conduction-type InAsSb layer is a first conduction-type InAs₁₋ₓSbₓ layer (0.0035≤x≤0.0065).

19. The method according to claim 13, further comprising a first metal electrode provided over the first conduction-type InAs layer.

20. A semiconductor device comprising:
a gallium antimonide (GaSb) substrate;
an active layer provided on the substrate, the active layer comprising an indium arsenide (InAs)/GaSb superlattice structure; and
a contact layer provided on the active layer, the contact layer comprising:
a first conduction-type InAsSb layer provided on the active layer and having a thickness of at least ten (10) nanometers; and
a first conduction-type InAs layer provided on the first conduction-type InAsSb layer,
the contact layer having a thickness of at least twenty (20) nanometers.
